(19) United States
(12) Patent Application Publication
(10) Pub. No.: US 2012/0312955 A1
(43) Pub. Date: Dec. 13, 2012

(54) Handle for hand held device

(76) Inventor: Ovie L. Randolph, Dallas County, TX (US)

(21) Appl. No.: 13/134,501

(22) Filed: Jun. 8, 2011

(51) Int. Cl. H05K 7/00

(52) U.S. Cl. 248/688

(57) ABSTRACT

A combined handle and stand for a hand held device, such as a notebook computer, forms a case with gripping edge guards on the left, the right, the bottom and the top, all of which are affixed to a back guard. The back guard forms a support ring and a snap-lock. A circular handle support fits into support ring and forms a receptacle for mating with snap-lock. A handle is mounted into opening of circular handle support so that handle pivots from one edge between an open position and a closed position. The handle forms a cut-out to make room for snap-lock. The opening, at the edge opposite pivot edge, forms a recess for ease of opening the handle from the closed position. Once in the open position, the handle can be gripped by a human user with the non-dominant hand of the user so that the user can then use the dominant hand for input to the hand held device. The circular handle support can turn to four stable positions. A pair of legs are pivotally mounted in side gripping edge guards, forming a stand for the hand held device when in the open position. When the legs are in the open position, then the combined handle and stand can rest on a table or desk or other surface at an angle, thereby supporting the hand held device at an angle. When not in use, the legs are pivoted into the closed position.

### CROSS-REFERENCE TO RELATED APPLICATIONS

### STATEMENT REGARDING FEDERALLY SPONSORED RESEARCH OR DEVELOPMENT.

Not Applicable

### INCORPORATION-BY-REFERENCE OF MATERIAL SUBMITTED ON A COMPACT DISC.

Not Applicable

### BACKGROUND OF THE INVENTION

1. Field of the Invention

The present invention relates generally to handles and stands for hand held devices and in particular to hand held computers

2. Description of Related Art

U.S. Pat. No. 5,349,497 Hanson et al. and U.S. Pat. No. 6,708,887 Garrett et al. show detachable handles for hand held devices. The handles do not rotate to other positions and do not fold into a closed position.

### BRIEF SUMMARY OF THE INVENTION

A combined handle and stand for a hand held device, such as a notebook computer, forms a case with a left gripping edge guard, a right gripping edge guard, a bottom gripping edge guard and a top gripping edge guard, all of which are affixed to a back guard. The back guard forms a support ring and a snap-lock. A circular handle support fits into support ring and forms a receptacle for mating with snap-lock. A handle is mounted into opening of circular handle support so that handle pivots from one edge between an open position and a closed position. The handle forms a cut-out to make room for snap-lock. The opening, at the edge opposite pivot edge, forms a recess for ease of opening the handle from the closed position. Once in the open position, the handle can be gripped by a human user with the non-dominant hand of the user so that the user can then use the dominant hand for input to the hand held device. The circular handle support can turn to four stable positions up, down, left and right.

One leg is pivotally mounted in left gripping edge guard and another leg is pivotally mounted in right gripping edge guard, forming a stand for the hand held device when in the open position. When the legs are in the open position, then the combined handle and stand can rest on a table or desk or other surface at an angle, thereby supporting the hand held device at an angle for easier access than when the hand held device is flat on the surface. When not in use, the legs are pivoted into the closed position.

These and other objects, advantages and features of this invention will be apparent from the following description taken with reference to the accompanying drawing, wherein is shown a preferred embodiment of the invention.

### BRIEF DESCRIPTION OF THE SEVERAL VIEWS OF THE DRAWING

FIG. 1 is a front left top perspective view of a handle and stand for a hand held device according to the present invention in the closed position, the front of the handle and stand facing the back of the hand held device;

FIG. 2 is a front left top perspective view of the handle and stand of FIG. 1 for a hand held device according to the present invention in the open position for the handle and the closed position for the stand; and

FIG. 3 is a front left top perspective exploded view of the handle and stand of FIG. 1 for a hand held device according to the present invention in the closed position for the handle and the open position for the stand;

### DETAILED DESCRIPTION OF THE INVENTION

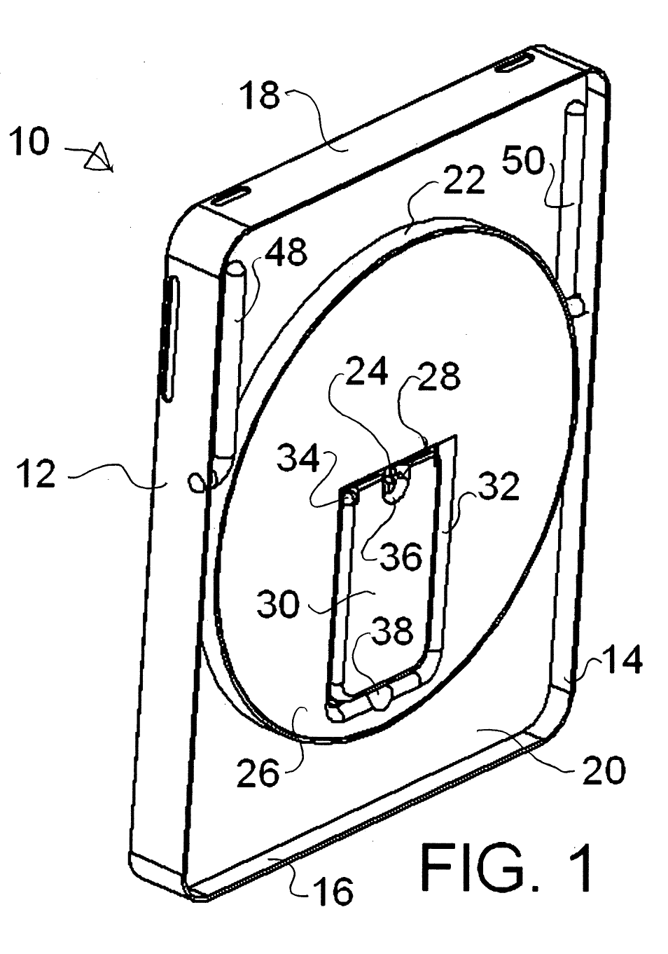

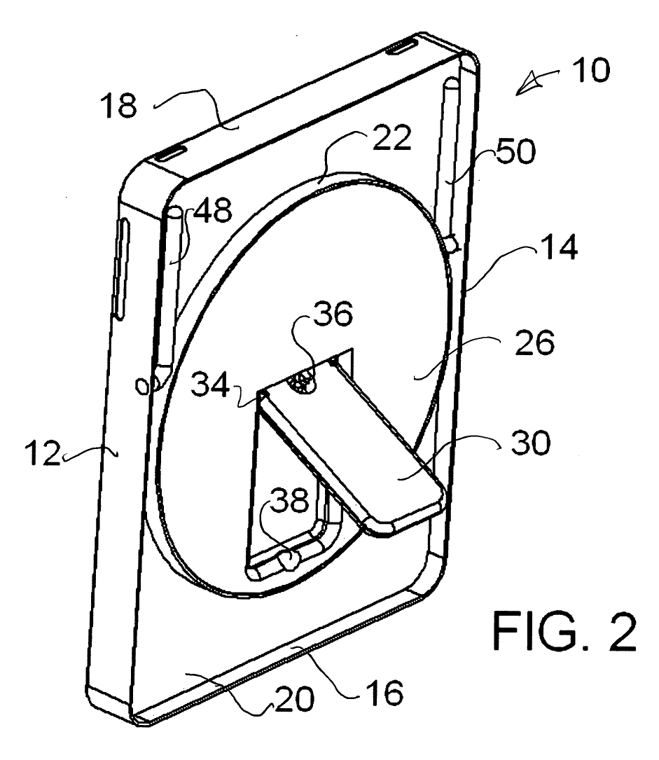

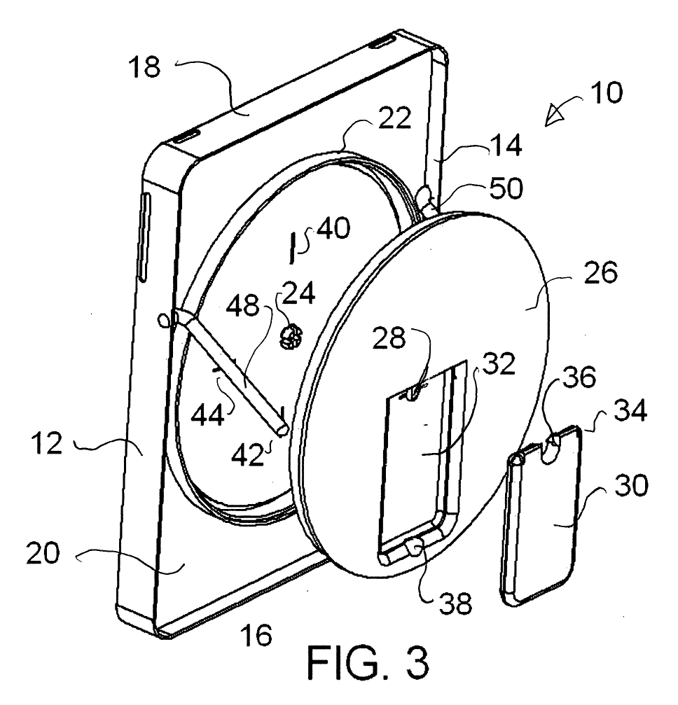

Referring now to the drawing, and in particular to FIG. 1 and FIG. 3, a combined handle and stand for a hand held device, such as a notebook computer, is referred to generally by reference numeral 10. In a preferred form, combined handle and stand 10 forms a case with a left gripping edge guard 12 which would be on the right facing the front of the hand held device, a right gripping edge guard 14 which would be on the right facing the front of the hand held device, a bottom gripping edge guard 16 and a top gripping edge guard 18, all affixed to a back guard 20. Back guard 20 forms a support ring 22 and a snap-lock 24. A circular handle support 26 fits into support ring 22 and forms a receptacle 28 for mating with snap-lock 24. A handle 30 is mounted into opening 32 of circular handle support 26 so that handle 30 pivots from one edge between an open position and a closed position, in a preferred form, from the edge 34 that is closest to the center of circular handle support 26. Handle 30 forms a cut-out 36 to make room for snap-lock 24. Referring also to FIG. 2, opening 32, at the edge opposite pivot edge 34, forms a recess 38 for ease of opening handle 30 from the closed position. Once in the open position, handle 30 can be gripped by a human user with the non-dominant hand of the user so that the user can then use the dominant hand for input to the hand held device. Circular handle support 26 can turn to four stable positions up 40, down 42, left 44 and right 46, not shown.

In one preferred form, leg 48 pivotally mounted in left gripping edge guard 12 and leg 50 pivotally mounted in right gripping edge guard 14, form a stand for the hand held device when in the open position shown in FIG. 3. When the legs are in the open position, then combined handle and stand 10 can rest on a table or desk or other surface at an angle, thereby supporting the hand held device at an angle for easier access than when the hand held device is flat on the surface. When not in use, leg 48 and leg 50 are pivoted into the closed position shown in FIG. 1 and FIG. 2.

From the foregoing it will be seen that this invention is well adapted to attain all of the ends and objectives hereinabove set forth, together with other advantages which are inherent to the apparatus.

It will be understood that certain features and subcombinations are of utility and may be employed without reference to other features and subcombinations. This is contemplated by and is within the scope of the claims.

As many possible embodiments may be made of the invention without departing from the scope thereof, it is to be understood that all matter herein set forth or shown in the figures of the accompanying drawings is to be interpreted as illustrative and not in a limiting sense.

1. A combined handle and stand for a hand held device, such as a notebook computer, comprising in combination:
a case forming a back guard and also forming a left gripping edge guard, which would be on the right facing the front of the hand held device, a right gripping edge guard, which would be on the right facing the front of the hand held device, a bottom gripping edge guard and a top gripping edge guard, all affixed to the back guard, wherein the back guard forms a support ring;
a circular handle support, which fits into the support ring and forms an opening for receiving a handle and a receptacle for mating with the snap-lock;
a handle mounted into the opening of circular handle support so that the handle pivots from one edge between an open position and a closed position from the edge that is closest to the center of circular handle support, thereby providing a handle to be held by one hand of a user or a stand to rest against a substantially horizontal surface, raising the hand held device to an angle suitable for viewing or to support against an edge of a non-horizontal surface, holding the hand held devices at a suitable angle.

2. A combined handle and stand for a hand held device according to claim 1, wherein the back guard also forms a snap-lock and the handle forms a cut-out to make room for the snap-lock.

3. A combined handle and stand for a hand held device according to claim 2, wherein the opening, at the edge opposite pivot edge, forms a recess for ease of opening the handle from the closed position, whereby when the handle is in the open position, the handle can be gripped by a human user with the non-dominant hand of the user so that the user can then use the dominant hand for input to the hand held device.

4. A combined handle and stand for a hand held device according to claim 3, wherein the circular handle support can turn to four stable positions up, down, left and right.

5. A combined handle and stand for a hand held device according to claim 4, further including:
a first leg pivotally mounted in the left gripping edge guard and second leg pivotally mounted in the right gripping edge guard, where in the combined first leg; and
a second leg form a stand for the hand held device when in the legs are in the open position, whereby when the legs are in the open position, the combined handle and stand can rest on a table or desk or other surface at an angle, thereby supporting the hand held device at an angle for easier access than when the hand held device is on the surface.

6. A combined handle and stand for a hand held device according to claim 2, wherein the circular handle support can turn to four stable positions up, down, left and right.

7. A combined handle and stand for a hand held device according to claim 6, further including:
a first leg pivotally mounted in the left gripping edge guard and second leg pivotally mounted in the right gripping edge guard, where in the combined first leg; and
a second leg form a stand for the hand held device when in the legs are in the open position, whereby when the legs are in the open position, the combined handle and stand can rest on a table or desk or other surface at an angle, thereby supporting the hand held device at an angle for easier access than when the hand held device is on the surface.

8. A combined handle and stand for a hand held device according to claim 2, further including:
a first leg pivotally mounted in the left gripping edge guard and second leg pivotally mounted in the right gripping edge guard, where in the combined first leg; and
a second leg form a stand for the hand held device when in the legs are in the open position, whereby when the legs are in the open position, the combined handle and stand can rest on a table or desk or other surface at an angle, thereby supporting the hand held device at an angle for easier access than when the hand held device is on the surface.

9. A combined handle and stand for a hand held device according to claim 1, wherein the opening, at the edge opposite pivot edge, forms a recess for ease of opening the handle from the closed position, whereby when the handle is in the open position, the handle can be gripped by a human user with the non-dominant hand of the user so that the user can then use the dominant hand for input to the hand held device.

10. A combined handle and stand for a hand held device according to claim 9, wherein the circular handle support can turn to four stable positions up, down, left and right.

11. A combined handle and stand for a hand held device according to claim 10, further including:
a first leg pivotally mounted in the left gripping edge guard and second leg pivotally mounted in the right gripping edge guard, where in the combined first leg; and
a second leg form a stand for the hand held device when in the legs are in the open position, whereby when the legs are in the open position, the combined handle and stand can rest on a table or desk or other surface at an angle, thereby supporting the hand held device at an angle for easier access than when the hand held device is on the surface.

12. A combined handle and stand for a hand held device according to claim 1, wherein the circular handle support can turn to four stable positions up, down, left and right.

13. A combined handle and stand for a hand held device according to claim 12, further including:
a first leg pivotally mounted in the left gripping edge guard and second leg pivotally mounted in the right gripping edge guard, where in the combined first leg; and
a second leg form a stand for the hand held device when in the legs are in the open position, whereby when the legs are in the open position, the combined handle and stand can rest on a table or desk or other surface at an angle, thereby supporting the hand held device at an angle for easier access than when the hand held device is on the surface.

14. A combined handle and stand for a hand held device according to claim 1, further including:
a first leg pivotally mounted in the left gripping edge guard and second leg pivotally mounted in the right gripping edge guard, where in the combined first leg; and
a second leg form a stand for the hand held device when in the legs are in the open position, whereby when the legs are in the open position, the combined handle and stand can rest on a table or desk or other surface at an angle, thereby supporting the hand held device at an angle for easier access than when the hand held device is on the surface.
